(19) United States
(12) Patent Application Publication
(10) Pub. No.: US 2006/0109884 A1
(43) Pub. Date: May 25, 2006

(54) Distributed feedback semiconductor laser and method for manufacturing the same

(75) Inventors: Young-Hyun Kim, Suwon-si (KR); Jung-Kee Lee, Suwon-si (KR); In Kim, Suwon-si (KR); Sung-Soo Park, Suwon-si (KR)

Correspondence Address: CHA & REITER, LLC, 210 ROUTE 4 EAST STE 103, PARAMUS, NJ, 07652, US

(73) Assignee: Samsung Electronics Co., LTD

(21) Appl. No.: 11/250,209

(22) Filed: Oct. 14, 2005

(30) Foreign Application Priority Data
Nov. 24, 2004 (KR) 2004-97126

(51) Int. Cl. H01S 5/00; H01S 3/08

(52) U.S. Cl. 372/96; 372/46.013; 372/50.11

(57) ABSTRACT

A distributed feedback semiconductor laser oscillating in a single mode and a method for manufacturing the same is disclosed. The distributed feedback semiconductor laser includes an active layer; a clad layer formed adjacent to the active layer; and diffraction gratings periodically formed in the clad layer and separated from each other by a predetermined distance. The diffraction gratings are formed of a nonconductor so that a current injected into the active layer is partially blocked and distribution of gain coefficient is varied. The nonconductor is an oxidized semiconductor material.

### CLAIM OF PRIORITY

This application claims priority to an application entitled “DISTRIBUTED FEEDBACK SEMICONDUCTOR LASER AND METHOD FOR MANUFACTURING THE SAME,” filed with the Korean Intellectual Property Office on Nov. 24, 2004 and assigned Ser. No. 2004-97126, the contents of which are incorporated herein by reference.

### BACKGROUND OF THE INVENTION

1. Field of the Invention

The present invention relates to a distributed feedback semiconductor laser, and more particularly to a distributed feedback semiconductor laser oscillating in a single mode and a method of manufacturing the same.

2. Description of the Related Art

Distributed feedback (DFB) semiconductor lasers are used as a light source for optical communication. The distributed feedback semiconductor laser includes a diffraction grating disposed on an active layer generating a laser light. It operates in a single mode by the wave selectiveness. The distributed feedback semiconductor laser is widely used in long distance high speed communication.

According to conventional methods for realizing the distributed feedback semiconductor lasers, gains may be periodically obtained or difference of index may be periodically detected by using diffraction gratings in a resonance length of the laser. Devices made according such methods are called index-coupled DFB lasers and gain-coupled DFB lasers, respectively. Since the indexes are also changed periodically in almost all the gain-coupled DFB lasers, the gain-coupled DFB lasers are also called ‘complex-coupled DFB lasers’.

In the case of the index-coupled DFB laser, by periodically detecting the difference of the index in diffraction gratings and reducing the number of possible oscillation modes, the oscillation in a single wave can be generated. Generally, the DFB laser has a problem in that the diffraction gratings of a light emitting surface are arbitrarily cut off and the oscillation of the single wave is restricted to within 30%.

To the contrary, in the case of the complex-coupled DFB laser, since the gain in an active layer itself can be periodically detected in a resonance length, the complex-coupled DFB laser is less affected by the fact that diffraction gratings on a light emitting surface is cut off irregularly. Since the line width enhancement factor of an oscillated mode is small, the complex-coupled DFB has excellent transmission characteristics.

Conventionally methods for realizing complex-coupled DFB lasers include a method, as disclosed in Japanese Patent Laid-Open No. 11-150339. In this method, an active layer is periodically etched and the gain of the active layer is periodically regulated. However, the disclosed method has following disadvantages. First, since the etched degree of the active layer greatly affects the difference of the gain, the etching depth must be accurately regulated. However, since the thickness of each layer in MQW is under 100 Å, the etching depth is very difficult to regulate. Second, since the active layer is etched directly, it may be damaged during the etching process and the interior loss becomes larger. Third, when re-growth is performed on the periodically etched active layer, the active layer is collapsed by the re-growth temperature. It is therefore difficult to maintain accurate diffraction gratings.

Related to the process in which the active layer is periodically etched, a method has bee proposed in which diffraction gratings are formed that capable of blocking a current on an active layer. The introduction of the current is locally differentiated and the gain is locally differentiated. However, according to this method, diffraction gratings of n-type are generally formed in a clad layer of p-type. Since depletion degrees are different according to doping degrees of each of the layers, the current blocking characteristics become different. Therefore, if biases are applied much, the current may not be blocked and the overall difference of the gain may disappear.

### SUMMARY OF THE INVENTION

One aspect of the present invention relates to a distributed feedback semiconductor laser which includes nonconductive diffraction gratings so that current introduction into the active layer is spatially differentiated, thereby changing distribution of gain coefficient.

Another aspect of the present invention relates a method for manufacturing a distributed feedback semiconductor laser including nonconductive diffraction gratings, by which the distributed feedback semiconductor laser can be easily manufactured.

One embodiment of the present invention is directed to a distributed feedback semiconductor laser including an active layer; a clad layer formed adjacently to the active layer; and diffraction gratings formed in the clad layer and periodically arranged at a predetermined interval. The diffraction gratings are formed of a nonconductor made from oxidized semiconductor material, which partially blocks a current injected into the active layer, thereby changing distribution of gain coefficient.

The nonconductor may include at least one of group III elements, group V elements, Se, Te, Zn, Ti, Cd, and Mg, and Al₂O₃.

The nonconductor may be formed above or below the active layer or may be formed both above and below the active layer.

Another embodiment of the present invention is directed to a method for manufacturing a distributed feedback semiconductor laser including an active layer a clad layer formed so as to be adjacent to the active layer; and diffraction gratings periodically formed in the clad layer and separated from each other by a predetermined distance. The method includes the steps of forming the diffraction grating patterns in the clad layer, the diffraction grating patterns being formed of a semiconductor layer including an easily oxidizable material; and forming nonconductive diffraction gratings by oxidizing the diffraction grating patterns.

The first forming step may include the sub-steps of growing the clad layer to a partial thickness among the predetermined entire thickness, forming the semiconductor layer including the easily oxidizable material on the clad layer and patterning the semiconductor layer to have a same pattern as the predetermined diffraction gratings and re-growing the clad layer to the predetermined rest of the thickness so as to cover the diffraction grating patterns completely.

The second forming step may include the sub-steps of etching the clad layer, the diffraction grating patterns, the active layer, and the semiconductor substrate to have a mesa structure, so that the diffraction grating patterns are exposed and oxidizing the diffraction grating patterns and thus changing the diffraction grating patterns to a nonconductor.

### BRIEF DESCRIPTION OF THE DRAWINGS

The above and other aspects, features, and embodiments of the present invention will be more apparent from the following detailed description taken in conjunction with the accompanying drawings, in which:

FIG. 1 is a perspective view for showing a distributed feedback semiconductor laser according to the first embodiment of the present invention;

FIGS. 2a to 2f are views for showing an example of a manufacturing process of the distributed feedback semiconductor laser of FIG. 1;

FIG. 3 is a perspective view for showing a distributed feedback semiconductor laser according to the second embodiment of the present invention; and

FIG. 4 is a perspective view for showing a distributed feedback semiconductor laser according to the third embodiment of the present invention.

### DETAILED DESCRIPTION

Hereinafter, embodiments of the present invention will be described with reference to the accompanying drawings. It is noted that the same reference numerals are used with respect to the same elements even in different drawings. For the purposes of clarity and simplicity, a detailed description of known functions and configurations incorporated herein is omitted to avoid obscuring the subject matter of the present invention.

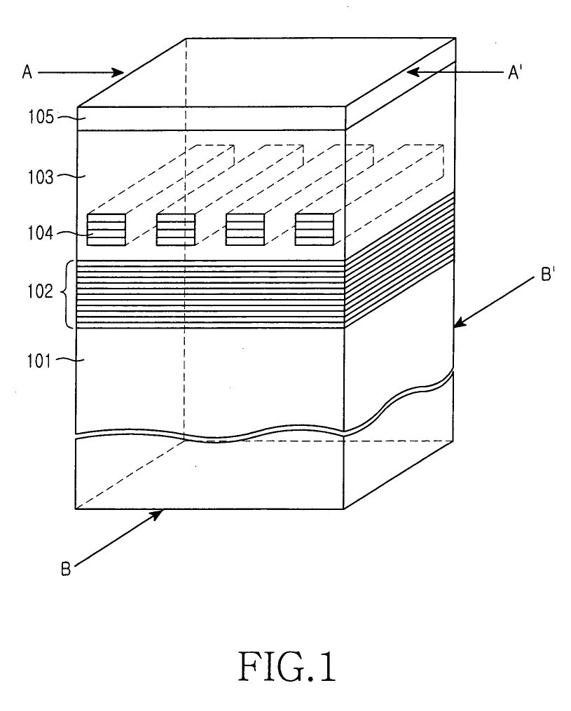

FIG. 1 is a perspective view for showing a distributed feedback semiconductor laser 100 according to the first embodiment of the present invention.

The distributed feedback semiconductor laser 100 includes a substrate 101, an active layer 102 formed on the substrate 101 and a clad layer 103, which is formed on the active layer 102 and of a different conductive type from the substrate 101. The laser 100 also includes diffraction gratings 104 periodically formed in the clad layer 103 and separated from each other by a predetermined distance, a contact layer 105, which is formed on the upper portion of the clad layer 103 and of a different conductive type from the substrate 101.

The substrate 101 is an n-type compound semiconductor substrate. The active layer 102 of a MQW (multiple quantum well) structure in which several n-type compound semiconductor layers are stacked. The clad layer 103 of p-type is formed on the active layer 102. The above structure is not deviated greatly from the application range of the material and thickness of a general distributed feedback semiconductor laser. Therefore, in the explanation of the this embodiment, the diffraction gratings 104, which is the characteristic structure, will be described in detail.

The diffraction gratings 104 are made of a nonconductor formed by oxidation of a semiconductor material. The diffraction gratings 104 are separated from each other by a predetermined distance, and are disposed in the clad layer 103 of the upper portion of the active layer 102. The diffraction gratings 104 function as a current support layer for spatially regulating the current introduction to the active layer 102. The gain coefficient in the active layer 102 is periodically changed by the diffraction gratings 104 of a nonconductor. In this way distributed feedback of light is generated and the required single mode oscillation can be obtained. By making the diffraction gratings with a nonconductor formed by oxidation of a semiconductor material, the clad layer 103 is easily grown on the diffraction gratings 104 and can close the diffraction gratings 104 completely without causing the generation of void.

In the distributed feedback semiconductor laser of FIG. 1, assuming that the contact layer 105 is of p-type and the substrate 101 is of n-type, if a positive bias is applied between the contact layer 105 and the substrate 101, current is injected into the active layer 102. Since the diffraction gratings 104 are periodically disposed at an interval in an area close to the active layer 102 in the clad layer 103, the distribution of current injected into the active layer 102 is spatially differentiated and the change of the gain coefficient is generated. The change of the gain coefficient generates distributed feedback of light and the required single mode oscillation can be obtained.

The manufacturing method of the distributed feedback semiconductor laser will now be described.

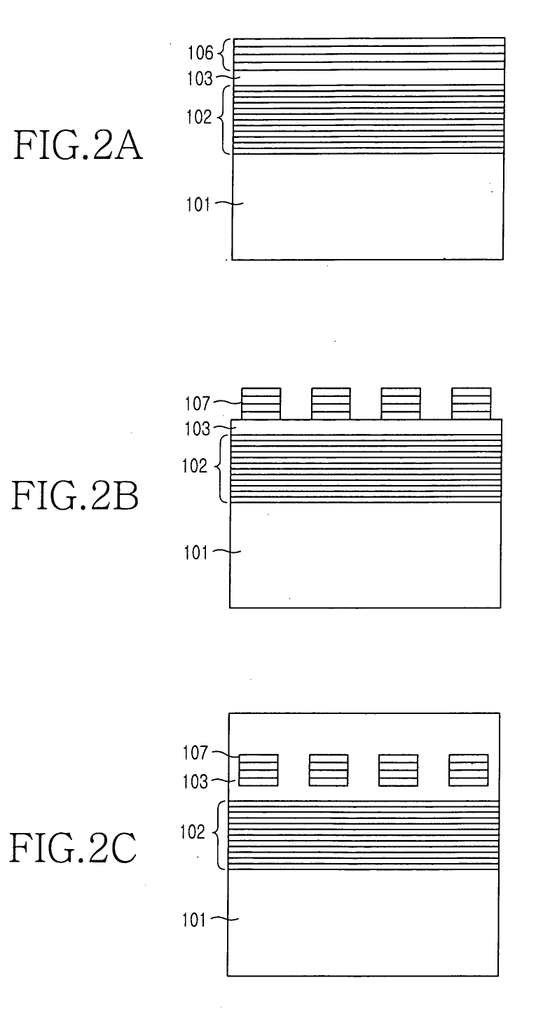

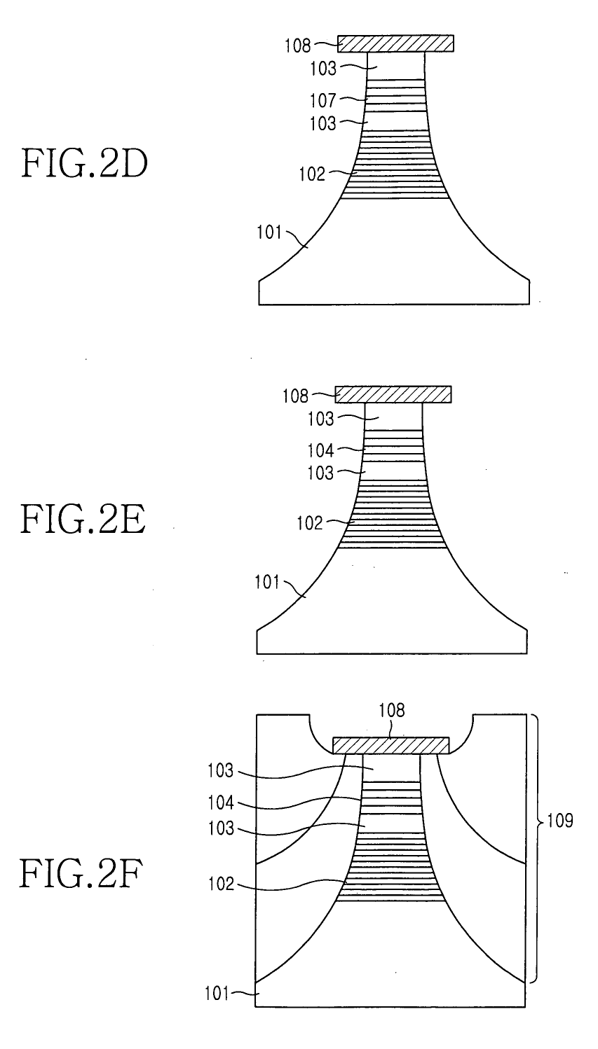

FIGS. 2a to 2f are views for showing an example of a manufacturing process of the distributed feedback semiconductor laser 100 of FIG. 1. FIGS. 2a to 2c are cross-sectional views taken along line A-A′ of FIG. 1, and FIGS. 2d to 2f are cross-sectional views taken along line B-B′ of FIG. 1.

First, as shown in FIG. 2a, the active layer 102 of a MQW structure in which several n-type compound semiconductor layers are stacked is grown on the n-type substrate 101. The p-type clad layer 103 is grown on the active layer 102. Thereafter, a structure in which AlAs and AlInAs are alternatingly stacked is grown on the clad layer 103 as a semiconductor layer 106 including an easily oxidizable material. The semiconductor layer 106, including the oxidizable material, becomes a nonconductor by an oxidation process which will be mentioned later. The easily oxidizable material includes group III elements, group V elements, Se, Te, Zn, Mg, Cd, etc.

Referring to FIG. 2b, diffraction grating patterns 107 of prearranged period are formed on a structure in which the AlAs and AlInAs layers are alternatingly stacked by using an E-beam or holographic method.

Referring to FIG. 2c, the p-type clad layer 103 may be grown on the diffraction grating patterns 107 using a method of MOCVD, MBE, or the like.

Referring to FIG. 2d, after a mask pattern 108 for mesa-etching is formed on the clad layer 103, the cross-section of the diffraction grating pattern of a stacked structure of the AlAS and AlInAs layers is exposed by proceeding the etching process using the mask pattern as an etching mask.

Referring to FIG. 2e, the diffraction grating pattern of the stacked structure of the AlAS and AlInAs layers, the cross-section of which is exposed by the process of FIG. 2d, is oxidized by an oxidation process. By the oxidation process, the diffraction grating pattern of the stacked structure of the AlAS and AlInAs layers is converted into a nonconductive body 104 including Al₂O₃. By forming the nonconductive diffraction gratings by the oxidation of the semiconductor layer, the generation of a void can be prevented when the clad layer is re-grown at the upper portion of the diffraction grating.

Referring to FIG. 2f, after the oxidation process, a current blocking layer 109 formed of a clad layer of p-type and n-type is formed on the side walls of the messa structure. Thereafter, although not shown, after the mask pattern 108 is removed, the contact layer is formed on the clad layer 103.

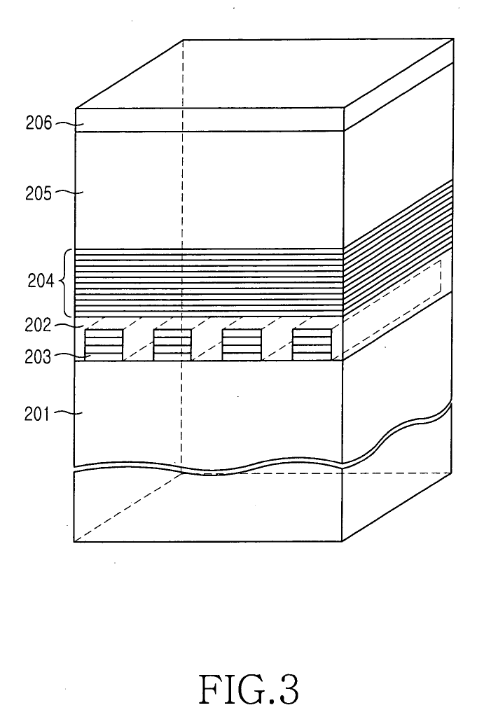

FIG. 3 is a perspective view for showing a distributed feedback semiconductor laser 200 according to the second embodiment of the present invention.

The distributed feedback semiconductor laser 200 includes a substrate 201, a clad layer 202 which is formed on the substrate 201 and of the same conductive type as the substrate 201 and nonconductive diffraction gratings 203 periodically formed in the clad layer 202 and separated from each other by a predetermined distance. The laser 200 also includes an active layer 204 formed on the clad layer 202, a contact layer 206 which is formed on the upper portion of the clad layer 205 and of a different conductive type from the substrate 201. In the second embodiment, the nonconductive diffraction gratings 203 are formed below the active layer 204. By spatially differentiating the electron carrier (in the case of n-type substrate) injected from the substrate direction, the local difference of the gain coefficient is obtained. Since the structure and operation of the nonconductive diffraction gratings 203 are the same as in the first embodiment, except for the position thereof, their detailed description will be omitted.

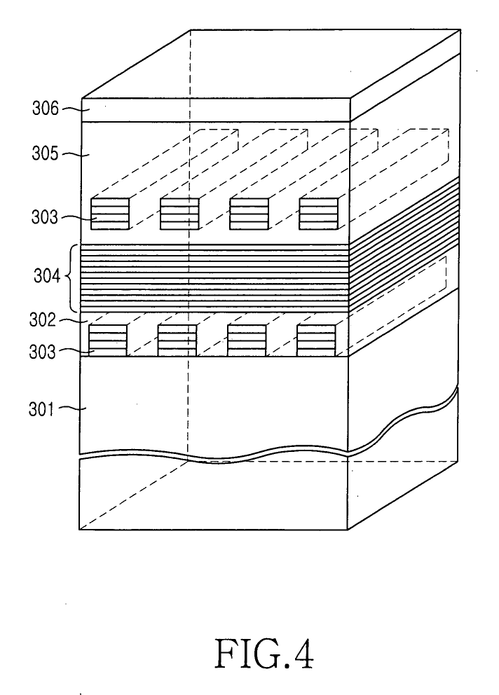

FIG. 4 is a perspective view for showing a distributed feedback semiconductor laser 300 according to the third embodiment of the present invention.

The distributed feedback semiconductor laser 300 includes a substrate 301, a clad layer 302 which is formed on the substrate 301 and of the same conductive type as the substrate 301 and nonconductive diffraction gratings 303 periodically formed in the clad layer 302 and separated from each other by a predetermined distance The laser 300 also includes an active layer 304 formed on the clad layer 302, a clad layer 305 which is formed on the active layer 304 and of the different conductive type from the substrate 301, nonconductive upper diffraction gratings 303 periodically formed in the clad layer 305 and separated from each other by a predetermined distance, and a contact layer 306 which is formed on the clad layer 305 and of a different conductive type from the substrate 201. In the third embodiment, the nonconductive diffraction gratings 303 are formed both below and above the active layer 304. By spatially differentiating the hole and the electron carrier injected from n and p sides, a greater local difference of the gain coefficient can be obtained. Since the structure and operation of the nonconductive diffraction gratings 303 are the same as in the first embodiment, except for the position thereof, their detailed description will be omitted.

As described above, by forming the diffraction gratings formed around the active layer with the nonconductor formed by the oxidation of a semiconductor material so that the distribution of the current injected into the active layer is spatially differentiated, the generation of a void can be prevented when the clad layer is re-grown and the diffraction gratings can be covered with the clad layer completely. Therefore, a single mode oscillation that can prevent stress and irregular reflection due to the void and can be used in a long distance high speed communication can be obtained.

While the invention has been shown and described with reference to certain embodiments thereof, it will be understood by those skilled in the art that various changes in form and details may be made therein without departing from the spirit and scope of the invention as defined by the appended claims.

What is claimed is:

1. A distributed feedback semiconductor laser comprising:
an active layer;
a clad layer formed adjacent to the active layer; and
diffraction gratings formed in the clad layer and periodically arranged at a predetermined interval,
wherein the diffraction gratings are formed of a nonconductor made from oxidized semiconductor material, which partially blocks a current injected into the active layer.

2. A distributed feedback semiconductor laser according to claim 1, wherein the nonconductor comprises at least one of group III elements, group V elements, Se, Te, Zn, Ti, Cd, and Mg.

3. A distributed feedback semiconductor laser according to claim 1, wherein the nonconductor comprises Al₂O₃.

4. A distributed feedback semiconductor laser according to claim 1, wherein the nonconductor is formed above or below the active layer.

5. A distributed feedback semiconductor laser according to claim 1, wherein the nonconductor is formed both above and below the active layer.

6. A distributed feedback semiconductor laser comprising:
a substrate;
an active layer formed on the substrate;
a clad layer formed adjacent to the active layer; and
nonconductive diffraction gratings periodically arranged at a predetermined interval in the clad layer, the nonconductive diffraction gratings being formed by oxidizing a semiconductor material, so that a current injected into the active layer is partially blocked.

7. A distributed feedback semiconductor laser according to claim 6, wherein the nonconductive diffraction gratings are formed above or below the active layer.

8. A distributed feedback semiconductor laser according to claim 6, wherein the nonconductive diffraction gratings are formed both above and below the active layer.

9. A method for manufacturing a distributed feedback semiconductor laser comprising an active layer; a clad layer formed adjacent to the active layer; and diffraction gratings periodically formed in the clad layer and separated from each other by a predetermined distance, the method comprising the steps of:
(1) forming the diffraction grating patterns in the clad layer, the diffraction grating patterns being formed of a semiconductor layer comprising an easily oxidizable material; and
(2) forming nonconductive diffraction gratings by oxidizing the diffraction grating patterns.

10. A method according to claim 9, wherein the easily oxidizable material comprises at least one of group III elements, group V elements, Se, Te, Zn, Ti, Cd, and Mg.

11. A method according to claim 9, wherein the semiconductor material comprising the easily oxidizable material is formed by alternatingly stacking AlAs layers and AlInAs layers a plurality of times.

12. A method according to claim 11, wherein the nonconductive diffraction gratings comprise Al₂O₃.

13. A method according to claim 9, wherein step (1) comprises the sub-steps of:
growing the clad layer to a partial thickness among the predetermined entire thickness;
forming the semiconductor layer including the easily oxidizable material on the clad layer and patterning the semiconductor layer to have a same pattern as the predetermined diffraction gratings; and
re-growing the clad layer to the predetermined rest of the thickness to cover the diffraction grating patterns completely.

14. A method according to claim 9, wherein step (2) comprises the sub-steps of:
etching the clad layer, the diffraction grating patterns, the active layer, and the semiconductor substrate to have a mesa structure, so that the diffraction grating patterns are exposed; and
oxidizing the diffraction grating patterns and changing the diffraction grating patterns to a nonconductor.

15. A method for manufacturing a distributed feedback semiconductor laser, the method comprising the steps of:
(a) forming an active layer on a semiconductor substrate;
(b) forming a clad layer on the active layer, the clad layer being of a different type from the substrate;
(c) forming a semiconductor layer on the clad layer, the semiconductor layer including an easily oxidizable material;
(d) forming diffraction grating patterns of a predetermined period by etching the semiconductor layer;
(e) forming a clad layer of a different type from the substrate, so that the clad layer covers the diffraction grating patterns completely;
(f) etching the clad layer, the diffraction grating patterns, the active layer, and the semiconductor substrate so as to have a mesa-structure, so that the diffraction grating patterns are exposed;
(g) oxidizing the diffraction grating patterns and changing the diffraction grating patterns to a nonconductor; and
(h) forming a current blocking layer on a side wall of the mesa structure.
